(19) United States
(12) Patent Application Publication
(10) Pub. No.: US 2002/0153596 A1
(43) Pub. Date: Oct. 24, 2002

(54) Lead frame and semiconductor package formed using it

(76) Inventors: Kunihiro Tsubosaki, Tokyo (JP); Chikao Ikenaga, Tokyo (JP); Kenji Matsumura, Tokyo (JP)

Correspondence Address: FLYNN, THIEL, BOUTELL & TANIS, P.C., 2026 Rambling Road, Kalamazoo, MI, 49008-1699, US

(21) Appl. No.: 10/100,507

(22) Filed: Mar. 18, 2002

(30) Foreign Application Priority Data
Mar. 30, 2001 (JP) 2001-098420

(51) Int. Cl. H01L 21/44

(52) U.S. Cl. 257/666; 257/676; 257/677; 438/123

(57) ABSTRACT

In a lead frame used for forming semiconductor package, a roughened plating layer 10 with excessive uneven surface is formed at least on the surface of lead frame brought into contact with molding compound 7 and metallic plating is made on areas of the rough surface 10 needed for wire bonding to form plating portions for connection. The surface of lead frame at least brought into contact with molding compound is covered with roughened plating layer 10 with excessive uneven surface so that the adhesion of molding compound to the lead frame is excellent due to the function of the roughened plating layer anchoring molding compound 7 to the lead frame. Therefore, the package crack and the cut of wires do not occur.

### BACKGROUND OF THE INVENTION

1. Field of the Invention

The present invention belongs to technical field of semiconductor package of the type that a semiconductor device is mounted on a lead frame and the exterior of the semiconductor device; particularly the upper surface of semiconductor device is covered with molding compound.

2. Description of the Related Art

An example of semiconductor package is shown in FIG. 1. The semiconductor package shown in FIG. 1 is QFP (Quad Flat Package) being one of surface mount type package, in which leads are taken out of four sides of the package and the leads are formed into a shape of gull-wing. Concretely, the semiconductor package is comprised of die pad 2 supported by suspending leads positioned at four edges of lead frame 1, a semiconductor device 4 mounted on the die pad 2 through die bond paste layer 3, wires 6 electrically connecting between electrodes provided on the upper surface of the semiconductor device 4 and leads 5 of lead frame 1 and molding compound 7 covering the outside of semiconductor device 4 with wires 6 in a state where a part of leads 5 is exposed.

In a case that the above-mentioned semiconductor package is mounted on a printed circuit board, a semiconductor package is temporarily adhered to the printed circuit board, and thereafter the semiconductor package temporarily adhered to the printed circuit board is sent into infrared rays reflow equipment, vapor phase soldering equipment or air soldering. In the reflow process, semiconductor package is heated to 215˜240° C. At this time, there is a case where moisture absorbed in molding compound of the semiconductor package is rapidly vaporized in the package so that wrong states such as package crack and the cut of wires accompanied by the package crack occur.

Concretely, wrong modes occur through the following two mechanisms.

Mode A: as shown in FIG. 2, the lower side of die pad 2 comes off from molding compound 7 and the lower molding compound 7 swells so that stress occur in molding compound 7 at the lower side of die pad 2 to generate crack 8.

Mode B: as shown in FIG. 3, vapor vaporized from die bond paste layer 3 and vapor generated in surrounding molding compound 7 collect at an interface between die pad 2 and die bond paste layer 3. Peeling is generated at the interface between die pad 2 under the influence of the pressure of the generated vapor and die bond paste layer 3 and crack 9 is generated in the horizontal direction so as to cut wire 6.

On the other hand, in recent years, a social demand to free soldering from Pb is strong so that soldering made using solder containing no Pb is needed. Therefore, the mounting temperature is raised by about 20° C. as compared with conventional mounting temperature. The above-mentioned problem turns out to be serious more and more.

Further, as mode that wire is cut in the process of mounting semiconductor package on a printed circuit board given is the following mode in addition to the above-mentioned cut of wires generated as the result of package crack.

Mode C: in case of lead frame formed using Cu alloy, as shown in FIG. 4, lead 5 is expanded with heat, while the terminal of lead 5 is secured, in the soldering reflow process. As a result, relative slipping-off is produced between lead 5 and molding compound 7 surrounding the lead so that the cut of wires 6 is produced near the connecting portion of wire 6 connected with the molding compound. This produces thermal strain in proportion to a difference between the coefficient of thermal expansion of Cu alloy (α≈17×10⁻⁶/° C.) and the coefficient of thermal expansion of molding compound (α≈10˜15×10⁻⁶/° C.), since the latter is lower than the former. The thermal strain produces peeling at the interface between lead frame and molding compound, which results in the cut of wires 6.

Until now, as such reform measures against the crack of package and the cut of wires produced in the soldering reflow process carried out are various methods for the improvement of molding compound and the improvement of the shape of lead frame. The following two examples are given as examples of the improvement of adhesion between lead frame and molding compound made by the contrivance of surface treatment of lead frame.

A first reform measures is the sand blast method, wherein the outer lead portion except molding area is covered with a metallic mask, fine unevenness is formed in the surface of material of lead frame by sand blast through the metallic mask and then Ag plating is given partially on wire bonding portion such as the tip of lead. In this case, if the outer lead portion is also made rough, thin bur of molding compound pushed out to the outer lead portion in the molding process cannot be removed in the bur-removing process so that solder plating do not stick on the area of outer lead portion to which molding compound stuck, in the next process, by which the defective solder coating is produced. Accordingly, as the above-mentioned, it is needed that outer lead portion is covered with a metallic mask and only the surface of inner lead portion is made rough.

A second reform measures is the needle Cr—Zn alloy plating method, wherein Ag plating is given partially to the necessary part such as the top of inner lead portion, thereafter the needle Cr—Zn alloy plating is made on the whole the surface of lead frame, and the needle Cr—Zn alloy plating formed on Ag plating is separated from the Ag plating by electrically anodic-stripping the needle Cr—Zn alloy plating in stripping solution through the mask having an opening corresponding to the area of Ag plating layer to expose the surface of Ag plating layer on which wire-bonding is possible.

The former of the two conventional reform measures shows to a certain degree the effect of improvement for the crack of package. However, there are problems that the cost of sand blast process is high and; that strain is produced in the surface processed by sand blast since mechanical impact is given to the surface of lead material, so that the deformation of suspending lead and others is produced, which results in deterioration of the accuracy of position of die pad in the Z direction.

The latter of the two conventional reform measures shows to a certain degree the effect of improvement for the solder reflow crack or the cut of wires because the bonding strength at the interface between lead frame and molding compound is strong. However, it is needed for a plating jig having an opening corresponding to the tip of lead for covering any part except the tip of lead to be provided, wherein the most part of inner lead 5 cannot be covered with the plating jig in case of a lead frame 1 having short inner leads 5 such as QFN (Quad Flat Non-Leaded Package) shown in FIG. 5. Therefore, the necessary area of needle Cr—Zn alloy plating layer is dissolved in the process of exposing the Ag plating layer for wire bonding in the tip of lead so that the desired effect cannot be obtained. On the other hand, in case of a large package of inner lead such as QFP (Quad Flat Package) shown in FIG. 1, it is possible to leave the needle Cr—Zn alloy plating layer in the inner lead. However, in this case, it is difficult to perfectly cover the sides of lead with a plating jig so that it is difficult to leave the needle Cr—Zn alloy plating layer on the sides of lead. Accordingly, the effect of the protection of reflow crack is restricted.

It is thought that the needle Cr—Zn alloy plating is made on the whole surface of lead frame, and then Ag plating is made partially on the needle Cr—Zn alloy plating layer. However, in this case, the needle Cr—Zn alloy plating layer is dissolved in the Ag plating bath of strong alkaline solution. Accordingly, this method cannot be applied.

### SUMMARY OF THE INVENTION

Accordingly, it is an object of the present invention is to provide a lead frame in which the package crack and the cut of wires are not produced in the process of solder reflow and a semiconductor package formed using the lead frame.

In order to achieve the above-mentioned object, a lead frame, according to the present invention, is a lead frame used for forming semiconductor package, wherein a roughened plating layer with excessive uneven surface is formed at least on the surface of the lead frame brought into contact with molding compound and metallic plating is made on areas of the roughened plating layer needed for wire bonding to form plating portions for connection.

Further, a semiconductor package, according to the present invention, is a semiconductor package comprising a lead frame, a semiconductor device mounted on a die pad supported by a suspending lead of the lead frame, wires electrically connecting between electrodes of the semiconductor device and leads of the lead frame, molding compound for molding an area surrounding semiconductor device with wires in a state where a part of leads are exposed, wherein the semiconductor device is formed using the lead frame in which a roughened plating layer with excessive uneven surface is formed at least on the surface brought into contact with molding compound and metallic plating is made on areas of the roughened plating layer needed for wire bonding to form plating portions.

### BRIEF DESCRIPTION OF THE DRAWINGS

FIG. 1 is a sectional view showing QFP of one of semiconductor package.

FIG. 2 is an explanatory view of one faulty mode generated in mounting a semiconductor package on a printed circuit board.

FIG. 3 is an explanatory view of another faulty mode generated in mounting a semiconductor package on a printed circuit board.

FIG. 4 is an explanatory view of further another faulty mode generated in mounting a semiconductor package on a printed board.

FIG. 5 is a sectional view showing QFN of one of semiconductor package.

FIG. 6 is a sectional view showing QFP in which the present invention is applied.

FIG. 7 is a sectional view showing a state where MAP type QFP has not been divided into individual package yet.

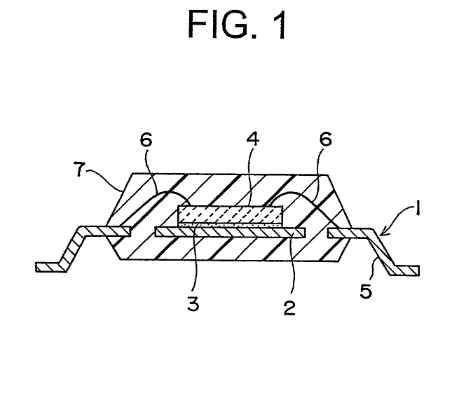

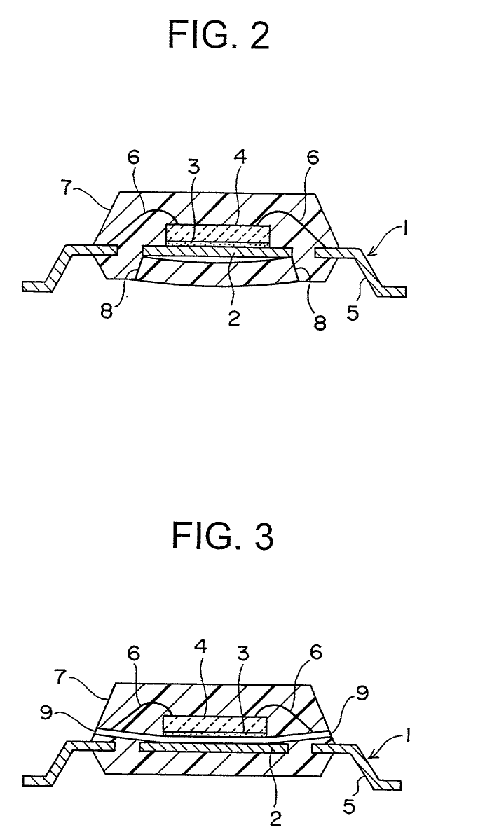

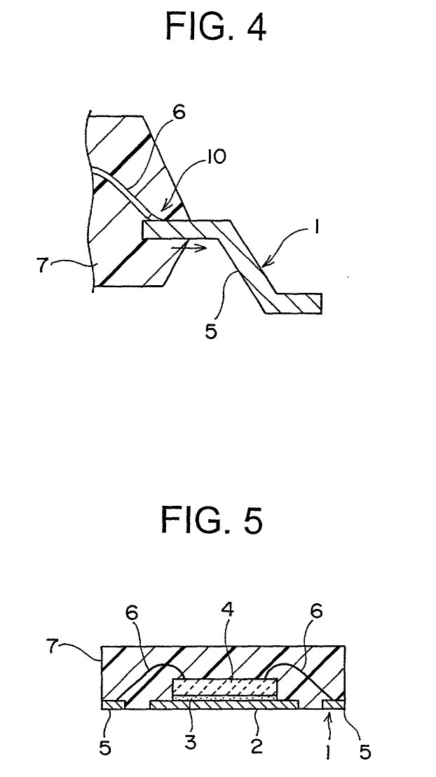

### PREFERRED EMBODIMENT OF THE INVENTION

Metallic materials used in a lead frame of the present invention can be ordinary materials used conventionally. Concretely, Cu alloy materials and Fe—Ni alloy materials may be applied.

Semiconductor package of the present invention includes surface mount type package such as QFP (Quad Flat Package), QFN (Quad Flat Non-Leaded Package) and SON (Small Outline Non-Leaded).

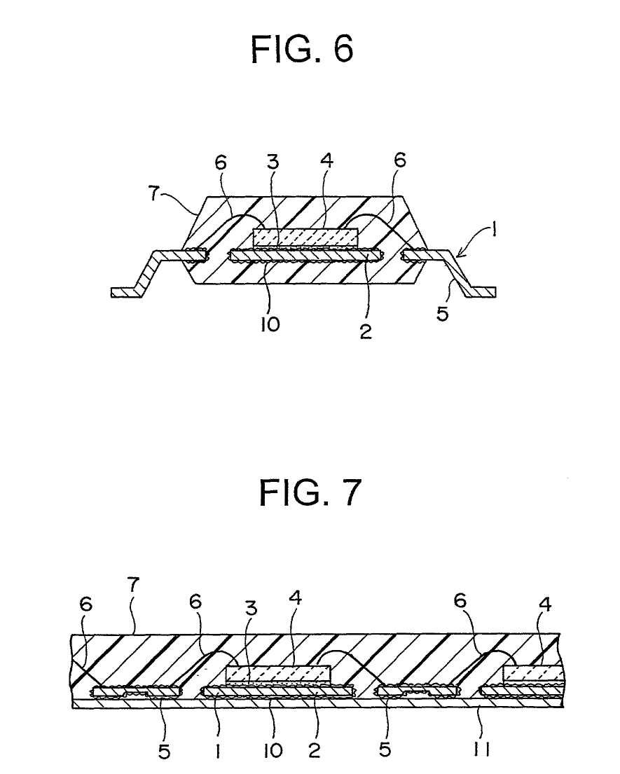

A roughened plating layer is given at least to an area of lead frame brought into contact with molding compound. For example, in the type of lead frame such as QFP shown in FIG. 6, a roughened plating layer 10 is given only to a part of the inside of package except outer lead. In such a way, a plating layer having rough surface is given to a part of the inside of package, wherein the structure of masking jig is relatively simple since an area of lead frame pressed with masking jig from both sides of lead frame is only an outer lead. In such a way, a roughened plating payer is given partially, while in a type such as the MAP (collectively molding) type QFN shown in FIG. 7 in which adhesive tape 11 is put on the lower surface of lead frame 1, the lead frame is molded with molding compound, the adhesive tape 11 is removed and thereafter solder plating is made on the lower surface of lead frame, a roughened plating layer 10 is given on the whole surface of lead frame 1. Namely, in the latter case, bur of molding compound does not enter the lower surface of lead since adhesive tape 11 is put on the lower surface of lead so that the problem of poor condition of solder wetting does not occur.

Wire bonding is hard to be made on the surface of roughened plating layer. Therefore, plating of another metal is applied on the necessary part for wire bonding to form a plating portion for connection. The plating portion for connection formed partially on lead is preferable to be formed of Ag. However, the plating portion for connection may be formed of Au or Pd. As the method of plating partially on lead, either a method of plating on lead through a mask or a method comprising the steps of forming a pattern with electrically deposited resist on lead and plating through the resist pattern on lead may be applied.

Concrete examples of plating layers formed on metallic materials of lead frames are given as following (1) to (4).

(1) “The whole surface Cu strike plating layer: 0.3 μm”/“roughened Cu plating layer: 2 μm”/“partial Ag plating layer: 5 μm”. In this example, the whole Cu strike plating layer is a ground layer for increasing the adhering strength of the roughened Cu plating layer to the metallic materials of lead frames.

(2) “The whole surface Cu strike plating layer: 0.3 μm”/“roughened Cu—Zn alloy plating layer: 2 μm”/“Cu flash plating layer: 0.2 μm (applied on partial area or the whole surface of the roughened Cu—Zn alloy plating layer)”/“partial Ag plating layer: 5 μm. In this example, when the Cu flash plating layer is applied on the whole surface of the roughened Cu—Zn alloy plating layer, the exposed area of Cu flash plating layer is removed.

(3) “The whole surface Cu strike plating layer: 0.3 μm”/“roughened Ni plating layer: 3 μm”/“Cu flash plating layer: 0.1 μm (applied on partial area or the whole surface of the roughened Ni plating layer)”/“partial Ag plating layer partial layer: 5 μm”. In this example, when the Cu flash plating layer is applied on the whole surface of the roughened Ni plating layer, the exposed area of Cu flash plating layer is removed.

(4) “The whole surface Cu strike plating layer: 0.3 μm”/“roughened Sn—Ni alloy plating layer: 2 μm”/“Cu flash plating layer: 0.1 μm (applied on partial area or the whole surface of the roughened Sn—Ni alloy plating layer)”/partial Ag plating layer: 5 μm”. In this example, when the Cu flash plating layer is applied on the whole surface of the roughened Sn—Ni alloy plating layer, the exposed area of Cu flash plating layer is removed.

In the fabricating process of semiconductor package, a lead frame is heated generally at 150 to 200° C. for one hour and further at 200 to 250° C. for 2 to 10 minutes. When the lead frame is heated, Copper oxide (CuO) film formed on the surface of common lead frame formed of Cu alloy is apt to peel off, which becomes the cause of worsening the adhering strength of molding compound to the surface of lead frame. When Cu—Zn plating layer, Ni plating layer or Sn—Ni plating layer is applied as roughened plating layer as mentioned in the above (2) to (4), these metals have the heat resistance and the bonding strength of oxide of these metals to ground layers is high. Therefore, the occurrence of peeling of molding compound is prevented by the cooperation of the high heat resistance, the high adhesive strength and the anchor effect of roughened plating.

Then, examples of lead frame and semiconductor package of the present invention are given.

### EXAMPLE 1

In the example 1, plating layers of the structure of layers mentioned in the above (1) were formed on a lead frame for QFP made of copper alloy metal sheet of “EFTEC-64T1/2H” with the thickness 0.125 mm and having the size of die pad of 10 millimeters square and the number of pins 208.

The forming of plating layers was made as follows. First, degreasing and acid pickling was made for the metal sheet having the shape of lead frame. Thereafter, Cu strike plating was carried out with the thickness 0.3 μm on the whole surface of the metal sheet in common cyanide bath. Then, roughened Cu plating layer with the thickness 2 to 3 μm was formed after outer lead portion of the metal sheet was covered with a masking jig, wherein the composition of plating bath was as follows: 50 to 150 g/l of CuSO₄.5H₂O and 5 to 100 g/l of H₂SO₄. Further, the condition of plating was as follows: the temperature of bath 20 to 40° C. and the current density of cathode (Dk) 10 to 20A/dm².

Then, Ag plating layer with the thickness 3 to 10 μm was formed using a masking jig having an opening at the position corresponding to the tip of inner lead. The Ag plating layer was formed by means of the sparger plating in common cyanide bath. Then, Ag deposited on the side of the metal sheet was removed by electrolysis. The metal sheet with plating layers was washed with water, and dried.

Semiconductor device was mounted on the lead frame manufactured as mentioned hereinbefore. Concretely, semiconductor device having the die size of 9.5 millimeters square was die-bonded with Ag paste on the lead frame and the Ag paste was hardened at 180° C. for one hour. Then, wire bonding was been carried out at 250° C. for three minutes. Thereafter, molding was carried out with epoxy resin, wherein epoxy resin was hardened at 180° C. for five hours. After the molding, the cutting of tie bar, de-bur, trimming and Sn plating were carried out in order. Thereafter, collectively molded lead frame was cut into individual semiconductor packages at the tip of lead. Finally, leads are formed to obtain the QFP type semiconductor package.

The QFP semiconductor package was allowed to stand at 85° C. and 85% RH for 168 hours to suck up water. Then, this semiconductor package was temporarily bonded to a printed circuit board. Thereafter, the solder reflow treatment was carried out by repeating three times the process of passing semiconductor package through the infrared reflow furnace at 260° C. for 15 seconds. The package crack was not found on inspection of the appearance of twenty semiconductor packages treated by the reflow process. Further, the peeling at inner lead and the interface between die pad and die bond paste layer was not found on the supersonic flaw detecting test or scanning acoustic flaw detecting test (SAT) of twenty semiconductor packages.

### EXAMPLE 2

In the example 2, plating layers of the structure of layers mentioned in the above (2) were formed on a lead frame for the MAP type QFN made of copper alloy metal sheet of “OLIN7025-H” with the thickness 0.2 mm and having the size of die pad of 2.0 millimeters square and the number of pins 20.

The forming of plating layers was made as follows. First, degreasing and acid pickling was made for the metal sheet having the shape of lead frame. Thereafter, Cu strike plating was carried out with the thickness 0.2 to 0.3 μm on the whole surface of the metal sheet in common cyanide bath. Then, roughened Cu—Zn alloy plating layer with the thickness 2 to 3 μm was formed on the whole surface of lead frame, wherein the composition of plating bath was as follows: 50 to 150 g/l of CuSO₄.5H₂O; 5 to 100 g/l of H₂SO₄ and; 100 to 1000 ppm of Zn⁺⁺ ion Further, the condition of plating was as follows: temperature of bath 20 to 40° C. and the current density of cathode (Dk) 10 to 20A/dm².

After roughened Cu—Zn alloy plating was made on the whole surface of the metal sheet, electrodepositing resist layer was formed on the whole surface of roughened Cu—Zn alloy plating layer. Concretely, “Eagle 2100ED (SHIPLEY Inc.)” was used as electrodepositing resist material and electrodepositing was made in solution of the electrodepositing resist material at 35° C. with applying a voltage of 100 V for 80 seconds. Then, exposure and development were made to form resist pattern having an opening at a position corresponding to the tip of lead. “Eagle 2005 (SHIPLEY Inc.)” was used as developing solution, wherein electrodepositing resist exposed was dipped in the developing solution at 40° C. for 60 seconds.

Then, Cu flash plating was made with the thickness 0.2 to 0.3 μm in the opening of resist pattern. The Cu flash plating was made in common Cu cyanide bath. Then, Ag plating was made with the thickness 3 to 10 μm in the same opening of resist pattern, wherein the Ag plating was made in common cyanide bath in the dipping plating method. Thereafter, the resist pattern was removed from lead flame. “Eagle 2009 (SHIPLEY Inc.)” was used as peeling solution, wherein the lead frame was dipped for 30 seconds in the peeling solution at 50° C. Finally, washing and drying were carried out.

Semiconductor device was mounted on the lead frame manufactured as mentioned hereinbefore. Concretely, first, adhesive tape was put on the whole surface of the back of lead frame. Then, semiconductor device having the die size of 1.8 millimeters square was die-bonded on the lead frame with Ag paste, and the Ag paste was hardened at 180° C. for one hour. Then, wire bonding was been carried out at 200° C. for 10 minutes. Thereafter, molding was correctively carried out with epoxy resin, wherein epoxy resin was hardened at 180° C. in five hours. After the molding, adhesive tape was removed from lead frame and Sn plating was carried out. Then, collectively molded lead frame was cut into individual semiconductor packages by dicing to obtain the QFN type semiconductor packages.

The obtained QFN semiconductor package was allowed to stand at 85° C. and 85% RH for 168 hours to suck up water. Then, this semiconductor package was temporarily bonded to a printed circuit board. Thereafter, the solder reflow treatment was carried out by repeating three times the process of passing semiconductor package through the infrared reflow furnace at 260° C. for 15 seconds. The package crack was not found on inspection of the appearance of semiconductor packages treated by the reflow process. Further, the peeling at inner lead and the interface between die pad and die bond paste layer was not found on the supersonic flaw detecting test or scanning acoustic flaw detecting test (SAT) of semiconductor packages.

### EXAMPLE 3

In the example 3, plating layers of the structure of layers mentioned in the above (3) were formed on a lead frame for the individual molding type QFN made of metal sheet of “OLIN7025-H” with the thickness 0.2 mm and having the size of die pad of 2.5 millimeters square and the number of pins 48.

The forming of plating layers was made as follows. First, degreasing, chemical polishing and acid pickling were made for the metal sheet having the shape of lead frame. Thereafter, Cu strike plating was carried out with the thickness 0.3 μm on the whole surface of the metal sheet in common cyanide bath. Then, roughened Ni plating layer with the thickness 2 to 4 μm was formed after outer lead of lead frame was covered with a masking jig, wherein the composition of plating bath was as follows: 200 g/l of NiSO₄.7H₂O; 100/l of NiCl₂.6H₂O and; 30 g/l of boric acid. Further, the condition of plating was as follows: temperature of bath 50° C. and the current density of cathode (Dk) 3A/dm².

After roughened Ni plating layer was formed, Cu flash plating was carried out with the thickness 0.1 μm. The Cu flash plating was carried out in common Cu cyanide bath. Then, Ag plating was carried out with the thickness 3 to 7 μm using a masking jig having an opening at a point corresponding to the tip of lead to form Ag plating layer in the opening. In this case, the Ag plating layer was formed by means of the sparger plating in common cyanide bath. Thereafter, the Cu flash plating layer was removed from the lead frame by the dipping method. Finally, washing and drying were carried out.

Semiconductor device with the die size 2.2 millimeters square was mounted on the lead frame manufactured as mentioned hereinbefore in the same manner as in Example 1 to obtain the QFN type semiconductor package. Then, evaluation was carried out in the same manner as in Example 1. However, the occurrence of package crack was not found. Further, the peeling at inner lead and the interface between die pad and die bond paste layer was not found.

### EXAMPLE 4

In Example 4, plating layers of the structure of layers mentioned in the above (4) were formed on a lead frame for the same QFN as in Example 3.

The forming of plating layers was carried out except the process of roughened plating in the same manner as in Example 3. Namely, in Example 4, roughened Sn—Ni alloy plating layer was carried out with the thickness 2 to 4 μm as roughened plating, wherein the composition of plating bath was as follows: 50 g/l of SnCl₂2H₂O; 400/l of NiCl₂.6H₂O; 30 g/l of NaF and; NH₄HF₂ 40 g/l. Further, the condition of plating was as follows: temperature of bath 60° C. and the current density of cathode (Dk) 2A/dm².

Semiconductor device with the die size 2.2 millimeters square was mounted on the lead frame manufactured as mentioned hereinbefore in the same manner as in Example 1 to obtain the QFN type semiconductor package. Then, evaluation was carried out in the same manner as in Example 1. However, the occurrence of package crack was not found. Further, the peeling at inner lead and the interface between die pad and die bond paste layer was not found.

In a semiconductor package of the present invention, the surface of lead frame at least brought into contact with molding compound is covered with roughened plating layer with excessive uneven surface so that the adhesion of molding compound to the lead frame is excellent due to the function of the roughened plating layer anchoring molding compound to the lead frame. Therefore, the package crack and the cut of wires do not occur. Particularly, the semiconductor package of the present invention can withstand the high temperature reflow in the process of freeing lead from Pb.

Further, the roughened plating can be made fully on the surface of lead frame brought into contact with molding compound including the side thereof even in the semiconductor package having short inner lead without the necessity of covering the tip of inner lead since the process of roughened plating is made prior to the formation of the plating portion for connections Therefore, plating deposited on the side is not dissolved as in the conventional needle Cr—Zn alloy plating method.

What is claimed is:

1. A lead frame used for forming semiconductor package, wherein a roughened plating layer with excessive uneven surface is formed at least on the surface of the lead frame brought into contact with molding compound and metallic plating is made on areas of the roughened plating layer needed for wire bonding to form plating portions for connection.

2. A semiconductor package comprising a lead frame, a semiconductor device mounted on a die mounting area, wires electrically connecting between electrodes of the semiconductor device and leads of the lead frame, molding compound for molding an area surrounding semiconductor device with wires in a state where a part of leads are exposed, wherein the semiconductor device is formed using the lead frame in which a roughened plating layer with excessive uneven surface is formed at least on the surface brought into contact with molding compound and metallic plating is made on areas of the roughened plating layer needed for wire bonding to form plating portions.
